(19) United States
(12) Patent Application Publication
(10) Pub. No.: US 2022/0093634 A1
(43) Pub. Date: Mar. 24, 2022

(54) SEMICONDUCTOR MEMORY DEVICE

(71) Applicant: KIOXIA CORPORATION, Tokyo (JP)

(72) Inventors: Akira TAKASHIMA, Fuchu Tokyo (JP); Tsunehiro INO, Fujisawa Kanagawa (JP); Yasushi NAKASAKI, Yokohama Kanagawa (JP); Yoshihiko MORIYAMA, Setagaya Tokyo (JP)

(21) Appl. No.: 17/189,218

(22) Filed: Mar. 1, 2021

(30) Foreign Application Priority Data
Sep. 18, 2020 (JP) 2020-157697

(51) Int. Cl. H01L 27/11582; H01L 29/51

(52) U.S. Cl. CPC H01L 27/11582; H01L 29/518; H01L 29/513

(57) ABSTRACT

According to one embodiment, a semiconductor memory device includes a stacked structure including conductive layers arranged in a first direction, and a columnar structure extending in the first direction in the first stacked structure. The columnar structure includes a semiconductor layer extending in the first direction, a charge storage layer between the semiconductor layer and the stacked structure, a first insulating layer between the semiconductor layer and the charge storage layer, and a second insulating layer between the stacked structure and the charge storage layer. The charge storage layer is aluminum nitride with a wurtzite crystal structure in which the c-axis is oriented in a direction towards the first insulating layer from the second insulating layer.

### CROSS-REFERENCE TO RELATED APPLICATION(S)

This application is based upon and claims the benefit of priority from Japanese Patent Application No. 2020-157697, filed Sep. 18, 2020, the entire contents of which are incorporated herein by reference.

### FIELD

Embodiments described herein relate generally to a semiconductor memory device.

### BACKGROUND

A NAND-type non-volatile semiconductor memory device, which includes a number of series-connected memory cells stacked on a semiconductor substrate, has been proposed.

### BRIEF DESCRIPTION OF THE DRAWINGS

FIG. 1 is a cross-sectional view schematically showing a configuration of a semiconductor memory device according to a first embodiment.

FIG. 2 is a cross-sectional view schematically showing a configuration of a semiconductor memory device according to a first embodiment.

FIG. 3 is a diagram depicting aspects related to an orientation direction of an aluminum nitride layer used as a charge storage layer in a semiconductor memory device according to a first embodiment.

FIG. 4 is a cross-sectional view schematically showing a configuration of a semiconductor memory device according to a second embodiment.

FIG. 5 is a cross-sectional view schematically showing a configuration of a semiconductor memory device according to a second embodiment.

### DETAILED DESCRIPTION

Embodiments provide a semiconductor memory device for which a decrease in the operating voltage is possible.

In general, according to one embodiment, a semiconductor memory device includes a stacked structure including conductive layers arranged in a first direction, and a columnar structure extending in the first direction through the stacked structure. The columnar structure includes a semiconductor layer extending in the first direction, a charge storage layer between the semiconductor layer and the first stacked structure, a first insulating layer between the semiconductor layer and the charge storage layer, and a second insulating layer between the stacked structure and the charge storage layer. The charge storage layer comprises aluminum nitride having a wurtzite crystal structure in which the c-axis is oriented in a direction towards the first insulating layer from the second insulating layer.

Embodiments of the present disclosure will now be described with reference to the drawings.

### First Embodiment

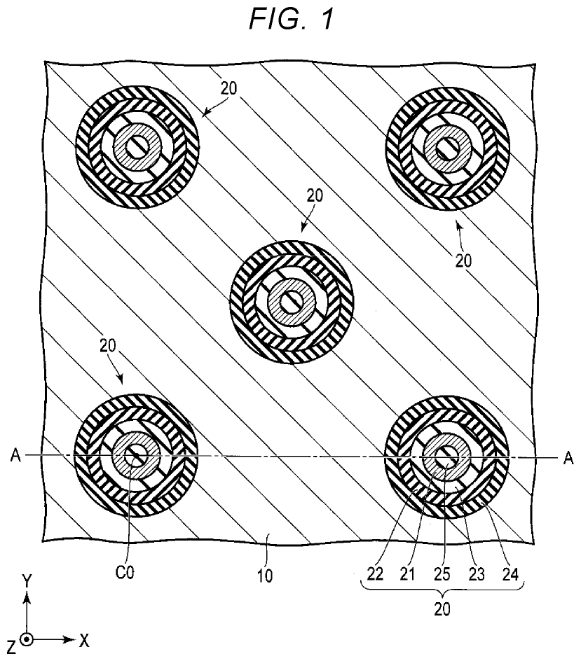

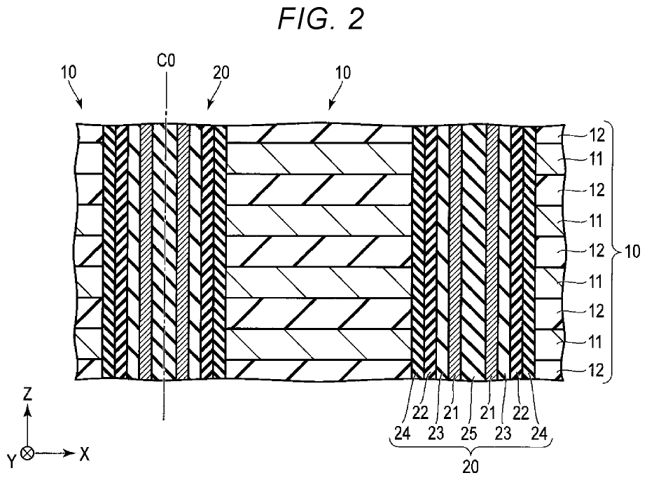

FIGS. 1 and 2 are cross-sectional views schematically showing a configuration of a NAND-type non-volatile semiconductor memory device according to a first embodiment. FIG. 1 is a cross-sectional view perpendicular to the Z direction, and FIG. 2 is a cross-sectional view parallel to the Z direction. FIG. 2 corresponds to the A-A cross-section of FIG. 1. The X direction, the Y direction and the Z direction, shown in FIGS. 1 and 2, are perpendicular to each other.

The semiconductor memory device shown in FIGS. 1 and 2 includes a stacked structure 10 and a plurality of columnar structures 20 provided adjacent to the stacked structure 10. The stacked structure 10 and the columnar structures 20 are integrated together on a semiconductor substrate or the like. A direction orthogonal to the main surface of such a semiconductor substrate corresponds to the Z direction.

The stacked structure 10 has a structure in which conductive layers 11 and insulating layers 12 are alternately stacked in the Z direction. Each conductive layer 11 is formed of a metal material such as tungsten (W), and functions as a word line. Each insulating layer 12 is formed of, for example, silicon oxide, and insulates the adjacent conductive layers 11 from each other.

The columnar structures 20 are arranged with respect to each other in a plane parallel to the X-Y plane perpendicular to the Z direction, and each columnar structure 20 extends in the Z direction. Each columnar structure 20 has a cylindrical shape, and the side surface of each columnar structure 20 is surrounded by the stacked structure 10.

Each columnar structure 20 includes a semiconductor layer 21, a charge storage layer 22, a tunnel insulating layer 23, a block insulating layer 24, and a core insulating layer) 25. The charge storage layer 22 is between the stacked structure 10 and the semiconductor layer 21. The tunnel insulating layer 23 is between the semiconductor layer 21 and the charge storage layer 22. The block insulating layer 24 is between the stacked structure 10 and the charge storage layer 22. The semiconductor layer 21 is between the tunnel insulating layer 23 and the core insulating layer 25. From another perspective, the block insulating layer 24 surround the charge storage layer 22, the charge storage layer 22 surrounds the tunnel insulating layer 23, the tunnel insulating layer 23 surrounds the semiconductor layer 21, and the semiconductor layer 21 surrounds the core insulating layer 25.

The semiconductor layer 21 has a cylindrical shape extending in the Z direction, and functions as a channel-forming region of a non-volatile memory cell. The semiconductor layer 21 is a silicon layer in this example.

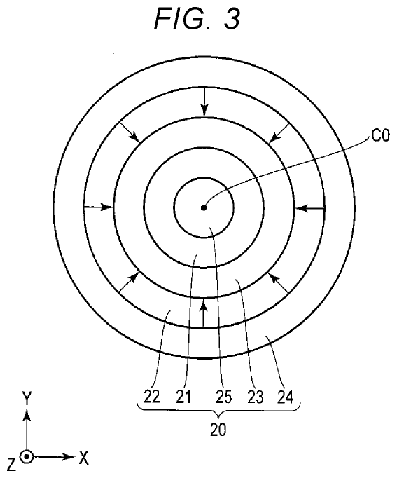

The charge storage layer 22 has a cylindrical shape extending in the Z direction, and functions as a charge trapping layer of a memory cell. The charge storage layer 22 is an aluminum nitride (AlN) layer having a wurtzite crystal structure in which the c-axis is oriented in a direction (as indicated by the arrows in FIG. 3) from the block insulating layer 24 toward the tunnel insulating layer 23. From another perspective, the aluminum nitride layer, constituting the charge storage layer 22, has a wurtzite crystal structure in which the c-axis is oriented in a direction toward the central axis C0 of the cylindrical columnar structure 20. From yet another perspective, the aluminum nitride layer, constituting the charge storage layer 22, has a wurtzite crystal structure in which the c-axis is oriented in a direction perpendicular to the interface between the charge storage layer 22 and the tunnel insulating layer 23 and also perpendicular to the interface between the charge storage layer 22 and the block insulating layer 24.

The tunnel insulating layer 23 has a cylindrical shape extending in the Z direction, and is a silicon nitride layer or a silicon oxynitride layer.

The block insulating layer 24 has a cylindrical shape extending in the Z direction, and is a silicon oxide layer or a silicon oxynitride layer.

The core insulating layer 25 is at the central axis C0 of the columnar structure 20 and has a cylindrical shape extending in the Z direction. The core insulating layer 25 is formed of, for example, silicon oxide.

In the semiconductor memory device, each conductive layer 11 and a portion of each columnar structure 20 which is surrounded by the respective conductive layer 11 constitute one memory cell. Thus, the semiconductor memory device functions as a NAND-type non-volatile memory including NAND strings each having memory cells connected in series along the Z direction.

As described above, in this first embodiment, the charge storage layer 22 is an aluminum nitride (AlN) layer having a wurtzite crystal structure in which the c-axis is oriented in a direction from the block insulating layer 24 toward the tunnel insulating layer 23. This makes it possible to decrease the operating voltage of the memory cells, as will be described further below.

Bulk aluminum nitride generally has a relative permittivity of about 8 to 9. On the other hand, aluminum nitride having a wurtzite crystal structure with an oriented c-axis has a relative permittivity of about 10.1, and thus has a higher relative permittivity than bulk aluminum nitride.

In this first embodiment, the aluminum nitride (AlN) layer forming charge storage layer 22 has a wurtzite crystal structure in which the c-axis is oriented in a direction from the block insulating layer 24 toward the tunnel insulating layer 23. Therefore, the capacitance of the charge storage layer 22, provided between the block insulating layer 24 and the tunnel insulating layer 23, can be increased. This makes it possible to decrease the applied voltage between each conductive layer 11, which functions as a gate electrode, and the semiconductor layer 21, thereby decreasing the operating voltage of the memory cells.

The coefficient of thermal expansion of aluminum nitride (AlN) is lower than that of silicon oxide. Therefore, when silicon oxide is used for the block insulating layer 24, the coefficient of thermal expansion of the charge storage layer 22 is lower than that of the block insulating layer 24. Thus, the block insulating layer 24 has a higher shrinkage percentage than the charge storage layer 22. Accordingly, a compressive stress is applied from the block insulating layer 24 to the charge storage layer 22 by the relative shrinkage of the block insulating layer 24. The compressive stress is applied in a direction from the block insulating layer 24 toward the tunnel insulating layer 23. This makes it possible to further increase the relative permittivity of the charge storage layer 22, thereby further decreasing the operating voltage of the memory cells.

Also if silicon oxynitride is used for the block insulating layer 24, the substantially the same effect can be achieved by adjusting the ratio between oxygen and nitrogen so that the coefficient of thermal expansion of the block insulating layer 24 is higher than that of the charge storage layer 22.

The charge storage layer 22 having the above-described crystal structure can be formed as follows. After forming memory holes (which are subsequently used for the formation of the columnar structures 20) in the stacked structure 10, an aluminum nitride layer is formed by atomic layer deposition (ALD) at a film-forming rate which is lower than standard or normal film-forming rate. This deposition method can form an aluminum nitride layer having the above-described wurtzite crystal structure with the oriented c-axis in each memory hole.

### Second Embodiment

The basic features of the second embodiment are similar to the features of the first embodiment, and therefore a duplicate description thereof is omitted.

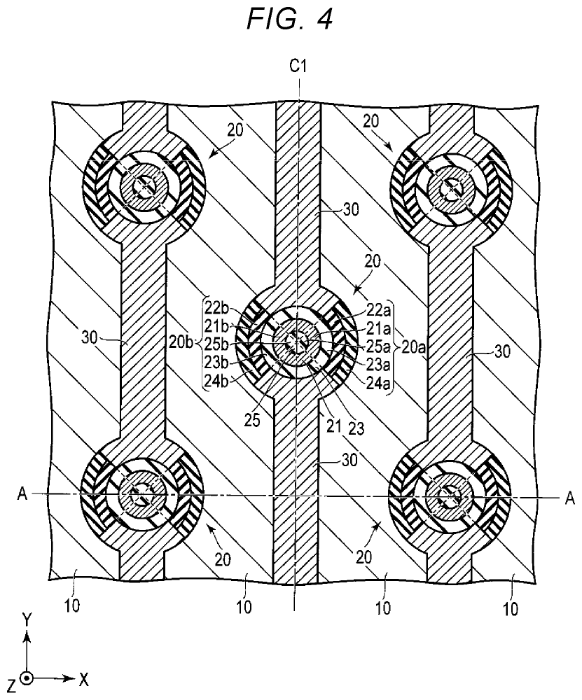

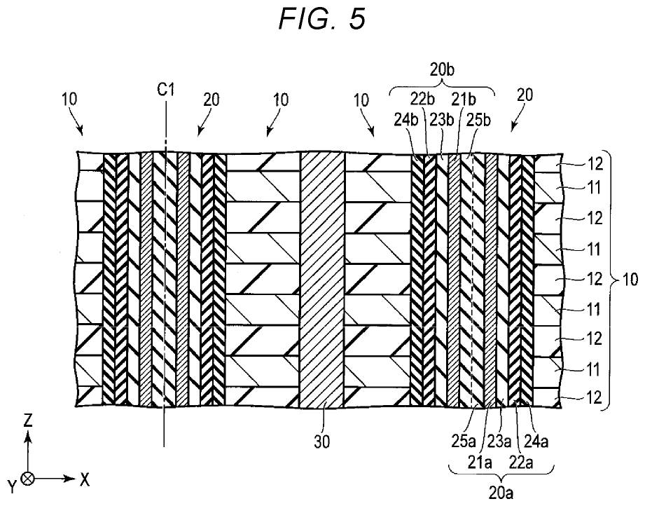

FIGS. 4 and 5 are cross-sectional views schematically showing a configuration of a NAND-type non-volatile semiconductor memory device according to this second embodiment. FIG. 4 is a cross-sectional view perpendicular to the Z direction, and FIG. 5 is a cross-sectional view parallel to the Z direction. FIG. 5 corresponds to the A-A cross-section of FIG. 4.

The semiconductor memory device of this second embodiment includes a plurality of spaced-apart (divided) stacked structures 10. A plurality of columnar structures 20 and a plurality of insulating structures 30 are provided alternately along the Y direction between adjacent stacked structures 10. The adjacent stacked structures 10 may be referred to as a first and second stacked structure 10 or an adjacent pair of stacked structures 10.

Each stacked structure 10, whose basic configuration is the same as that of the first embodiment, has a structure in which the conductive layers 11 and the insulating layers 12 are alternately stacked in the Z direction.

Each columnar structure 20 includes a first columnar portion 20a and a second columnar portion 20b. The first columnar portion 20a and the second columnar portion 20b are symmetrical with respect to a center line C1 extending in the Y direction, and have the same basic configuration as one another.

The first columnar portion 20a includes a first portion 21a of the semiconductor layer 21, a charge storage layer 22a, a first portion 23a of the tunnel insulating layer 23, a block insulating layer 24a, and a first portion 25a of the core insulating layer 25.

In particular, the charge storage layer 22a is between a first columnar portion 20a-side stacked structure 10 (e.g., the righthand most stacked structure 10 in FIG. 5) and the first portion 21a of the semiconductor layer 21. The first portion 23a of the tunnel insulating layer 23 is between the first portion 21a of the semiconductor layer 21 and the charge storage layer 22a. The block insulating layer 24a is between the first columnar portion 20a-side stacked structure 10 and the charge storage layer 22a. The first portion 21a of the semiconductor layer 21 is between the first portion 23a of the tunnel insulating layer 23 and the first portion 25a of the core insulating layer 25.

The second columnar portion 20b includes a second portion 21b of the semiconductor layer 21, a charge storage layer 22b, a second portion 23b of the tunnel insulating layer 23, a block insulating layer 24b, and a second portion 25b of the core insulating layer 25.

In particular, the charge storage layer 22b is between a second columnar portion 20b-side stacked structure 10 (e.g., the second from right stacked structure 10 in FIG. 5) and the second portion 21b of the semiconductor layer 21. The second portion 23b of the tunnel insulating layer 23 is between the second portion 21b of the semiconductor layer 21 and the charge storage layer 22b. The block insulating layer 24b is between the second columnar portion 20b-side stacked structure 10 and the charge storage layer 22b. The second portion 21b of the semiconductor layer 21 is between the second portion 23b of the tunnel insulating layer 23 and the second portion 25b of the core insulating layer 25.

Each insulating structure 30 is provided between a first columnar portion 20a and a second columnar portion 20b and also between the adjacent stacked structures 10, and is formed of, for example, a silicon oxide layer.

Similar to the first embodiment, in this second embodiment the charge storage layer 22a is an aluminum nitride (AlN) layer having a wurtzite crystal structure in which the c-axis is oriented in a direction from the block insulating layer 24a toward the first portion 23a of the tunnel insulating layer 23. Likewise, the charge storage layer 22b is an aluminum nitride (AlN) layer having a wurtzite crystal structure in which the c-axis is oriented in a direction from the block insulating layer 24b toward the second portion 23b of the tunnel insulating layer 23.

From another perspective, it can also be said that the aluminum nitride layer forming the charge storage layer 22a has a wurtzite crystal structure in which the c-axis is oriented in a direction perpendicular to the interface between the charge storage layer 22a and the first portion 23a of the tunnel insulating layer 23 and also perpendicular to the interface between the charge storage layer 22a and the block insulating layer 24a. Likewise, the aluminum nitride layer forming the charge storage layer 22b has a wurtzite crystal structure in which the c-axis is oriented in a direction perpendicular to the interface between the charge storage layer 22b and the second portion 23b of the tunnel insulating layer 23 and also perpendicular to the interface between the charge storage layer 22b and the block insulating layer 24b.

The materials of the semiconductor layer 21, the tunnel insulating layer 23, the block insulating layers 24a and 24b, and the core insulating layer 25 are the same as those of the first embodiment.

In this second embodiment, each conductive layer 11 and a portion of each columnar portion 20a which is located adjacent to the respective conductive layer 11 constitute one memory cell. Likewise, each conductive layer 11 and a portion of the columnar portion 20b which is located adjacent to the respective conductive layer 11 constitute another memory cell. Thus, in the semiconductor memory device of this second embodiment, two NAND strings are provided for each columnar structure 20.

As with the first embodiment, this second embodiment makes it possible to increase the relative permittivities of the charge storage layers 22a and 22b, thereby decreasing the operating voltage of the memory cells.

Though a silicon nitride layer or a silicon oxynitride layer is used as a tunnel insulating layer in the first and second embodiments, in other examples a silicon oxide layer may be used as a tunnel insulating layer.

Though a silicon oxide layer or a silicon oxynitride layer is used as a block insulating layer in the first and second embodiments, in other examples a silicon nitride layer may be used as a block insulating layer.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a stacked structure including conductive layers stacked on each other in a first direction, the conductive layers being spaced from each other in the first direction; and
a columnar structure extending in the first direction, the columnar structure including:
a semiconductor layer extending in the first direction,
a charge storage layer between the semiconductor layer and the stacked structure,
a first insulating layer between the semiconductor layer and the charge storage layer, and
a second insulating layer between the charge storage layer and the stacked structure and, wherein
the charge storage layer comprises aluminum nitride having a wurtzite crystal structure in which the c-axis is oriented in a direction towards the first insulating layer from the second insulating layer.

2. The semiconductor memory device according to claim 1, wherein the first insulating layer comprises silicon oxide, silicon nitride, or silicon oxynitride.

3. The semiconductor memory device according to claim 1, wherein the second insulating layer comprises silicon oxide, silicon nitride or silicon oxynitride.

4. The semiconductor memory device according to claim 1, wherein the coefficient of thermal expansion of the charge storage layer is lower than that of the second insulating layer.

5. The semiconductor memory device according to claim 1, wherein the second insulating layer applies a compressive stress to the charge storage layer.

6. The semiconductor memory device according to claim 1, wherein
the columnar structure further includes a third insulating layer extending in the first direction, and
the semiconductor layer is between the third insulating layer and the first insulating layer.

7. The semiconductor memory device according to claim 1, wherein the columnar structure is surrounded by the stacked structure in a plane perpendicular to the first direction.

8. The semiconductor memory device according to claim 7, wherein
the second insulating layer surrounds the charge storage layer in the plane perpendicular to the first direction,
the charge storage layer surrounds the first insulating layer in the plane perpendicular to the first direction, and
the first insulating layer surrounds the semiconductor layer in the plane perpendicular to the first direction.

9. The semiconductor memory device according to claim 1, wherein the columnar structure has a cylindrical shape.

10. The semiconductor memory device according to claim 1, further comprising:
a plurality of columnar structures each extending in the first direction through the stacked structure.

11. The semiconductor memory device according to claim 1, further comprising:
an insulating structure extending in the first direction through the stacked structure and dividing the stacked structure into a first portion and a second portion adjacent to the first portion in a second direction perpendicular to the first direction with the insulating structure therebetween, wherein
the columnar structure is between the first and second portions of the stacked structure in the second direction and adjacent to the insulating structure in a third direction perpendicular to the first and second directions.

12. A semiconductor memory device, comprising:
a first stacked structure including conductive layers stacked on each other in a first direction, the conductive layers of the first stacked structure being spaced from each other in the first direction;
a second stacked structure including conductive layers stacked on each other in the first direction, the conductive layers of the second stacked structure being spaced from each other in the first direction, second stacked structure being spaced from the first stacked structure in a second direction perpendicular to the first direction; and
a columnar structure extending in the first direction, the columnar between and adjacent to the first stacked structure and the second stacked structure in the second direction, the columnar structure including:
a semiconductor layer extending in the first direction,
a charge storage layer including a first portion between the first stacked structure and the semiconductor layer and a second portion between the second stacked structure and the semiconductor layer,
a first insulating layer including a first portion between the semiconductor layer and the first portion of the charge storage layer and a second portion between the semiconductor layer and the second portion of the charge storage layer, and
a second insulating layer including a first portion between the first stacked structure and the first portion of the charge storage layer and a second portion between the second stacked structure and the second portion of the charge storage layer, wherein
the first portion of the charge storage layer comprises aluminum nitride having a wurtzite crystal structure in which the c-axis is oriented in a direction towards the first portion of the first insulating layer from the first portion of the second insulating layer, and
the second portion of the charge storage layer comprises aluminum nitride having a wurtzite crystal structure in which the c-axis is oriented in a direction towards the second portion of the first insulating layer from the second portion of the second insulating layer.

13. The semiconductor memory device according to claim 12, further comprising:
an insulating structure between the first and second stacked structures in the second direction, wherein
the columnar structure is adjacent to the insulating structure in a third direction perpendicular to the first and second directions.

14. The semiconductor memory device according to claim 12, wherein the first and second stacked structures are electrically isolated from each other.

15. The semiconductor memory device according to claim 12, wherein
the first insulating layer comprises silicon oxide, silicon nitride, or silicon oxynitride, and
the second insulating layer comprises silicon oxide, silicon nitride, or silicon oxynitride.

16. The semiconductor memory device according to claim 12, wherein the coefficient of thermal expansion of the charge storage layer is lower than that of the second insulating layer.

17. The semiconductor memory device according to claim 12, wherein the second insulating layer applies a compressive stress to the charge storage layer.

18. A semiconductor memory device, comprising:
a conductive layer;
a semiconductor layer;
a charge storage layer between the conductive layer and the semiconductor layer in a first direction;
a first insulating layer between the semiconductor layer and the charge storage layer in the first direction; and
a second insulating layer between the conductive layer and the charge storage layer in the first direction, wherein
the charge storage layer comprises aluminum nitride having a wurtzite crystal structure in which the c-axis is oriented in a direction towards the first insulating layer from the second insulating layer.

19. The semiconductor memory device according to claim 18, further comprising:
a plurality of conductive layers stacked in a second direction perpendicular to the first direction, the conductive layers being spaced from each other in the second direction, wherein
the semiconductor layer extends in the second direction through the plurality of conductive layers,
the charge storage layer is between the semiconductor layer and each of the conductive layers, and
the second insulating layer is between the charge storage layer and each of the conductive layers.

20. The semiconductor memory device according to claim 18, wherein the conductive layer, the semiconductor layer, the charge storage layer, the first insulating layer, and the second insulating layer comprise a NAND memory cell.
